(19) United States
(12) Patent Application Publication
(10) Pub. No.: US 2001/0024393 A1
(43) Pub. Date: Sep. 27, 2001

(54) Memory-in recording medium controlling system and controller

(76) Inventor: Shinichi Kawano, Tokyo (JP)

Correspondence Address: William S. Frommer, Esq., FROMMER LAWRENCE & HAUG LLP, 745 Fifth Avenue, New York, NY, 10151, US

(21) Appl. No.: 09/783,654

(22) Filed: Feb. 14, 2001

(30) Foreign Application Priority Data
Feb. 16, 2000 (JP) 2000-043582

(51) Int. Cl. G11C 7/00

(52) U.S. Cl. 365/201

(57) ABSTRACT

For controlling a memory of a memory-in recording medium from an external device connected via a network, a controller 20 including an MIC data storage circuit 21 for provisional storage of the data format of an MIC, input unit 22 to enter characters etc., display unit 23 to display operations made, HDD 24 having stored therein various programs, data, etc., IEEE 1394 I/F circuit 25 being an interface with a transmission line 30, and a CPU 26 to control the units and circuit to execute processes, and a VCR to write and/or read to and from a DV tape 11 having an MIC 15 built therein, are connected to each other via the transmission line 30 being an IEEE 1394 serial bus cable.

### BACKGROUND OF THE INVENTION

1. Field of the Invention

The present invention relates to a memory-in recording medium controlling system to control the memory built in the memory-in recording medium via a network, and a controller to control a memory of a memory-in recording medium via a network.

2. Description of the Related Art

Some of the digital video tapes (will be referred to as “DV tape” hereinafter) for recording digital video and audio information, etc. have built in a cassette case thereof a nonvolatile memory capable of recording appended information such as tape position, comment on recorded image, etc. for easier and quicker access to the DV tape.

The memory built in the DV tape cassette case is called MIC (memory in cassette) and consists of a main area in which data such as tape information etc. are recorded, an optional area in which data such as index information, TOC (table of contents), etc. are recorded, and an unused area.

To edit the contents of an MIC built in the DV tape cassette case, it is necessary to operate the DV tape under the control from the main body of a digital video tape recorder in which the DV tape is loaded.

Also, when changing the contents of the MIC under the control from the main body of the digital video tape recorder, user-defined characters cannot be entered since the kinds of standard typefaces, number of input characters, etc. are limited.

### OBJECT AND SUMMARY OF THE INVENTION

It is therefore an object of the present invention to overcome the above-mentioned drawbacks of the prior art by providing a memory-in recording medium controlling system to control, via a network, the memory of the recording medium under the control from a controller connected to the controlling system.

It is also an object of the present invention to provide a controller for use as connected to a digital video recorder in which a memory-in recording medium is to be loaded for play to control the memory of the recording medium via a network.

The above object can be attained by providing a nonvolatile memory-in recording medium controlling system, including according to the present invention:

a recorder/player in which the recording medium is to be loaded, including:

means for writing and/or reading video and audio information to and/or from the memory-in recording medium; and

means for controlling data read and write from and to the nonvolatile memory; and

a controller connected to the recorded/player via a digital interface and including:

means for issuing a command for access to the nonvolatile memory via the digital interface and a command for data read from the nonvolatile memory and appending additional data to data thus read.

In the above, the controller has a storage means for storing data in the nonvolatile memory, the writing means writes data read from the nonvolatile memory to the storage means, the digital interface is an IEEE 1394 serial bus conforming to IEEE Standard 1394-1995 “IEEE Standard for a High Performance Serial Bus”, and the commands are AV/C commands transmitted by the function control protocol and transmitted and received by the asynchronous transfer.

The above writing means issues a command for access to the nonvolatile memory via the digital interface, a command for data read from the nonvolatile memory, and appends additional data to data thus read.

Therefore, in the memory-in recording medium controlling system according to the present invention, information stored in the memory of the recording medium is controlled and edited by the controller connected via the network. At this time, the controller saves the data format stored in the memory in the virtual array thereof and accesses the virtual array, whereby the time for information read and write can be reduced.

Also, the above object can be attained by providing a nonvolatile memory-in recording medium controller, including according to the present invention:

means for issuing a command for access to a nonvolatile memory of a nonvolatile memory-in recording medium via a digital interface and a command for data read from the nonvolatile memory and appending additional data to data thus read.

In the above, the controller has a storage means for storing data in the nonvolatile memory, the writing means writes data read from the nonvolatile memory to the storage means, the digital interface is an IEEE 1394 serial bus conforming to IEEE Standard 1394-1995 “IEEE Standard for a High Performance Serial Bus”, and the commands are AV/C commands transmitted by the function control protocol and transmitted and received by the asynchronous transfer.

The above writing means issues a command for access to the nonvolatile memory via the digital interface and a command for data read from the nonvolatile memory and appends additional data to data thus read.

Also, the controller can use character information prepared in advance when the data in the memory is changed. Therefore, the controller can advantageously permit the user to make a desired input of characters without various limitations which would be in the prior art.

These objects and other objects, features and advantages of the present intention will become more apparent from the following detailed description of the preferred embodiments of the present invention when taken in conjunction with the accompanying drawings.

### BRIEF DESCRIPTION OF THE DRAWINGS

FIG. 1 is a flow chart of operations effected in data write and/or read to and/or from a memory of a memory-in recording medium (DV tape) loaded in the controller provided in the memory-in recording medium controlling system according to the present invention;

FIG. 2 is a block diagram of the memory-in recording medium controlling system according to the present invention;

FIG. 3 shows an MIC record format stored in a virtual MIC array in an MIC data storage circuit;

FIG. 4 schematically illustrates a graphic-user interface screen presented on a display unit of the controller in the memory-in recording medium controlling system according to the present invention;

FIG. 5 is a flow chart of operations effected when the controller in the memory-in recording medium controlling system according to the present invention, reads the MIC data format; and

FIG. 6 is a flow chart of operations effected when the controller in the memory-in recording medium controlling system according to the present invention, adds a title, comment, etc. to user-defined positions.

### DETAILED DESCRIPTION OF THE PREFERRED EMBODIMENTS

The memory-in recording medium controlling system according to the present invention allows a controller connected via a digital interface to a video cassette recorder (will be referred to as “VCR” hereinafter) capable of write and/or read to and/or from a digital video tape (will be referred to as “DV tape” hereinafter) having a memory built therein to write and/or read data recorded in the memory of the DV tape.

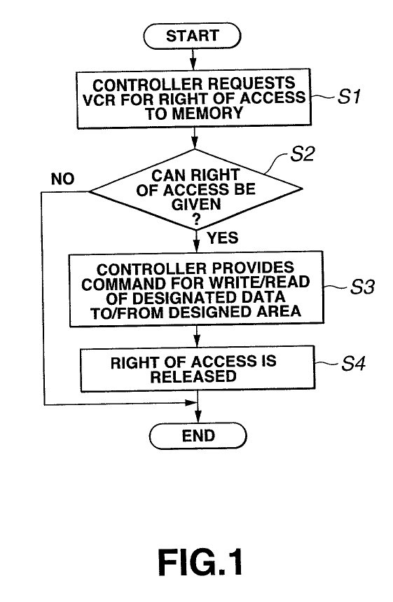

Referring now to FIG. 1, there is shown a flow chart of operations effected by the controller in the memory-in recording medium controlling system when writing and/or reading data to and/or from the memory of the DV tape.

At step S1, the controller requests the VCR for the right of access to the memory in the DV tape.

At step S2, the VCR judges whether the right of access can be given to the controller. For example, when no DV tape is loaded, when a DV tape is loaded but it has no memory provided therein, when a DV tape is loaded but protected against overwrite or when the VCR is effecting another operation, the VCR will determines that the right of access cannot be given to the controller. When thus inhibited from access to the VCR for any of the above reasons, the controller will stop from operating.

On the other hand, when given the right of access by the VCR, the controller will supply, at step S3, the VCR with a command for data read from a designated area in the memory and/or a command for data write to a designated area in the memory, and read and/or write data to and/or from the memory in the DV tape on the basis of the commands.

Upon completion of the data read and/or write, the controller will release the right of access to the memory at step S4.

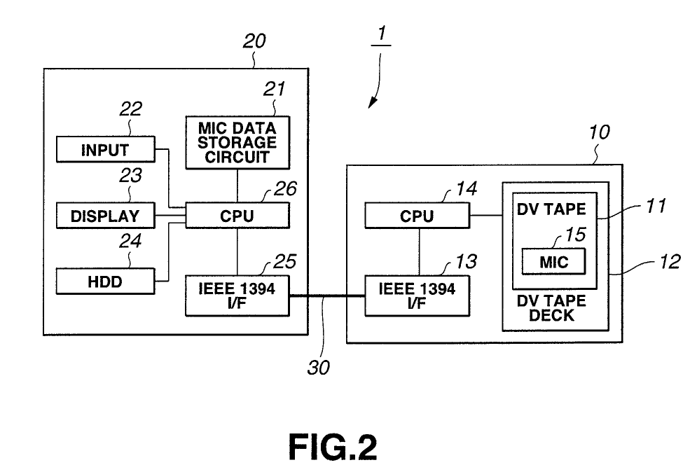

Referring now to FIG. 2, there is illustrated in the form of a block diagram the memory-in recording medium controlling system according to the present invention. An example construction of the controlling system will be described in detail below:

As shown in FIG. 2, the controlling system indicated generally with a reference 1 includes a VCR 10 capable of recording and/or playing back data to and/or from a memory-in DV tape, controller 20 to control the VCR 10, and a transmission line 30 to connect the VCR 10 and controller 20 to each other. The transmission line 30 is a digital interface which is an IEEE 1394 serial bus cable conforming to the IEEE Standard 1394-1995 “Standard for a High Performance Serial Bus”.

The “VCR” stands for video cassette recorder as having previously been described. The VCR 10 uses a DV tape 11 (will further be described later) which records video and audio information, etc. in a digital form. The DV tape 11 has a built-in MIC (memory in cassette) 15 being a nonvolatile memory. The VCR 10 includes a DV deck 12 to record and/or play back digital data to and/or from the DV tape 11, IEEE 1394 I/F (interface) circuit 13 interfacing with the transmission line 30 being an IEEE 1394 serial bus cable, and a CPU (central processing unit) 14 to control the operations of the DV deck 12 and IEEE 1394 I/F circuit 13.

As in the above, the DV tape 11 has built therein a nonvolatile memory capable of recording appended information such as tape position, comment on recorded images, etc. The nonvolatile memory will be referred to as “MIC (memory in cassette)” 15 hereinafter. The MIC 15 is controlled by a command sent from the controller 20 via the transmission line 30 to read and write data.

The DV deck 12 also includes a head to read and write digitized video and audio information, drive to drive the DV tape 11 during read and write, etc. (not shown). The DV deck 12 further includes a connector (not shown) which connects to the MIC 15 built in the DV tape 11 for data read and write to and from the MIC 15. The DV deck 12 reads digital video and audio information from the DV tape 11 and writes digital video and audio information to the DV tape 11. The DV deck 12 reads and writes data from and to the MIC 15.

The IEEE 1394 I/F circuit 13 supplies various data and asynchronous-signal command supplied from the CPU 14 to the controller 20 via the transmission line 30. The IEEE 1394 I/F circuit 13 supplies various data and asynchronous-signal command supplied from the controller 20 to the CPU 14.

The CPU 14 controls the operation of the DV deck 12 and data transmission operation of the IEEE 1394 I/F circuit 13. The CPU 14 is supplied, from the IEEE 1394 I/F circuit 13, with the command being a control instruction sent from the controller 20 via the transmission line 30.

On the other hand, the controller 20 in the controlling system 1 is provided to control the DV tape 11 loaded in the VCR 10 from outside the latter, and it can use a general-purpose personal computer (PC). As shown, the controller 20 includes an MIC data storage circuit 21 to provisionally store or buffer the MIC data format, input unit 22 to enter characters etc., display unit 23 to display the operational status etc., hard disc drive (HDD) 24 to store various programs to be executed by the CPU and various data, IEEE 1394 I/F circuit 25 which interfaces with the transmission line 30 being an IEEE 1394 serial bus cable, and a CPU 26 to control the above units and circuits for execution of each process.

The MIC data storage circuit 21 is provided to buffer data read from the MIC 15. In the MIC data storage circuit 21, there is defined a virtual MIC array which can be handled like the MIC 15 and in which the read data is saved. Therefore, since data having been read from the MIC 15 is edited for storage into the MIC data storage circuit 21, it can be read or written in a shorter time than in case the data is read or written by direct access to the MIC 15 at each time.

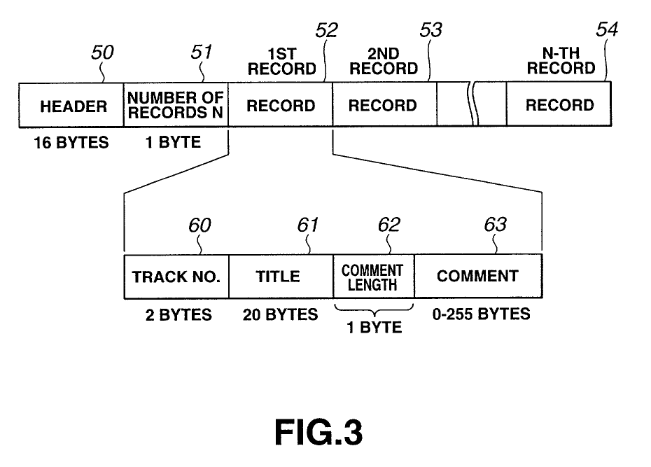

At this time, the data read from the MIC 15 is saved as a record format shown in FIG. 3 in the virtual MIC array in the MIC data storage circuit 21 according to an application. Namely, the record format of the MIC 15 consists of a 16-byte header 50, 1-byte number of records 51, first record 52, second record 53, third to (N-1)-th records (not shown), and an N-th record 54.

Further, each of the records consists of a 2-byte track number 60, 20-byte title 61, 1-byte comment length 62, and a comment 63 having a variable length between 0 and 255 bytes.

The input unit 22 is used by the user to enter characters etc. In the controlling system 1, the input unit 22 is a combination of a keyboard and a so-called mouse. The input unit 22 converts user-made character input and selection into signals which are sent to the CPU 26.

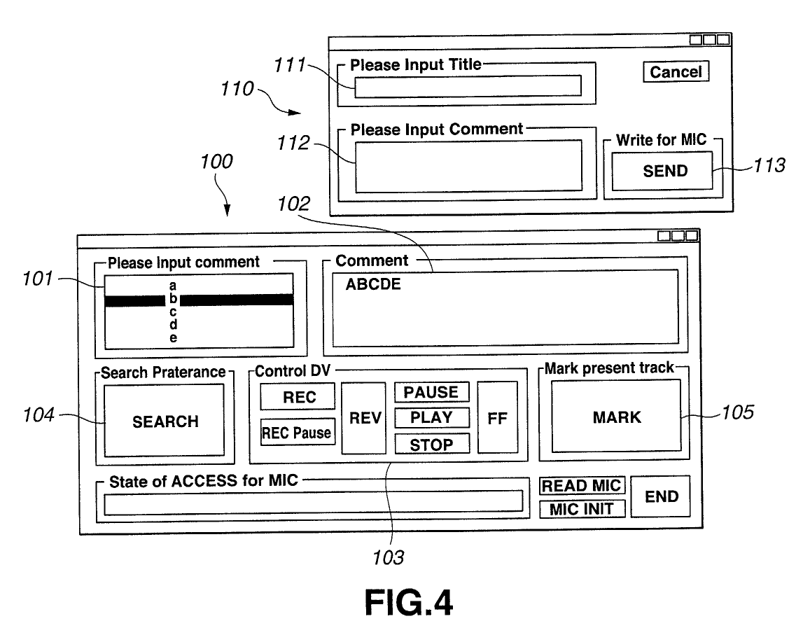

The display unit 23 is a liquid display for example, and its operation is controlled by the CPU 26. The display unit 23 displays a graphical user interface for entry of characters and selection of functions. For example, windows 100 and 110 are shown as an example of the graphical user interface in FIG. 4.

The window 100 has a title area 101 in which video titles recorded in the DV tape 11 are shown, comment area 102 in which a comment on a titled selected from the video titles in the title area 101 is shown, remote control area 103 with a plurality of tool buttons used to control the VCR 10 connected to the controlling system 1, SEARCH button 104 and a MARK button 105.

In the title area 101 shown in FIG. 4, there are shown titles “a”, “b”, “c”, “d” and “e” for videos, respectively, captured by the user. A comment “ABCDE” corresponding to the marked title “c” is shown in the commend area 102.

The window 110 has a title input area 111 in which characters or a sentence as a title is entered, comment input area 112 in which a comment is entered, and a SEND button 113.

More specifically, the SEARCH button 104 is provided to search a tape position where a titled video shown in the title area 101. The MARK button 105 is provided to mark a tape position where a title, comment or the like is added to the MIC 15. The SEND button 13 is provided to transmit, when adding a title and comment to the MIC, input characters to the MIC 15. These tool buttons are turned on and off by pointing the mouse pointer to them and clicking the mouse button.

The user can easily operate the controller 20 by operating the mouse to select one of the tool buttons in the graphical user interface screen shown as the windows 100 and 110. Also, the user can write character data to the MIC 15 by entering characters etc. to the title input area 111 and comment input area 112. As characters for entry to the windows, character information such as fonts, character size, number of input characters, etc. prepared in advance in the controller 20 can be used.

The HDD 24 has stored therein various programs to be executed by the CPU 26, various data, character information, etc. The HDD 24 supplies a program to the CPU 26 or stores data etc. supplied from the CPU 26.

The IEEE 1394 I/F circuit 25 supplies various data and asynchronous-signal command received from the CPU 26 to the VCR 10 via the transmission line 30, and supplies various data and asynchronous-signal command received from the VCR 10 to the CPU 26.

The CPU 26 controls the operation of each of the above units and data transmission and other operations of the IEEE 1394 I/F circuit 25. The CPU 26 supplies a command being a control instruction to the VCR 10 via the transmission line 30.

In the aforementioned memory-in recording medium controlling system 1, command used by the controller 20 to control the MIC 15 by means of the VCR 10 is the so-called AV/C command. The AV/C command is “AV/C digital interface command set VCR subunit specification command. The AV/C command and response are transmitted by the function control protocol (FCP). The FCP is a communications protocol defined in the IEC 61883 being a digital interface for consumer electronics—audio/video devices. This protocol is conveniently used for transfer of a command and response between such electronic devices. For transmission of, and response to, such an AV/C command, an asynchronous block write transaction conforming to the IEEE 1394 standard is used. The FCP frame is encapsulated to be an IEEE 1394 serial bus block write packet.

The AV/C commands include an “OPEN MIC command” to request the right of access to the MIC 15, “ABSOLUTE TRACK NUMBER status command” to acquire tape position information, “READ MIC command” to read MIC data, “WRITE MIC command” to write MIC data, etc. The “OPEN MIC command” has subfunctions “CLOSE”, “READ OPEN” and “WRITE OPEN” defined as operands.

The memory-in recording medium controlling system 1 including the aforementioned components makes basic operations for data transfer between the VCR 10 and controller 20 as will be described below:

In case data is supplied from the controller 20 to the VCR 10, when data for control of the VCR 10 is supplied from the input unit 22 of the controller 20 by the user, the entered control signal is sent from the input unit 22 to the CPU 26. The CPU 26 will deliver the entered data from the IEEE 1394 I/F circuit 25 to the transmission line 30. The VCR 10 will receive, at the IEEE 1394 I/F circuit 13, the data from the transmission line 30, and transmits them to the CPU 14. The CPU 14 will drive the DV deck 12 according to a control instruction corresponding to the control signal.

Since the AV/C command is so defined that the signal receiver has to return the result of an operation effected under the command to the signal transmitter, the VCR 10 operates according to the received control signal and transmits the result of the operation to the controller 20 via the transmission line 30. The controller 20 will receive the operation result via the IEEE 1394 I/F circuit 25. The controlling system 1 may be adapted such that at this time, the operation result is displayed on the display unit and also the user is noticed of the operation result.

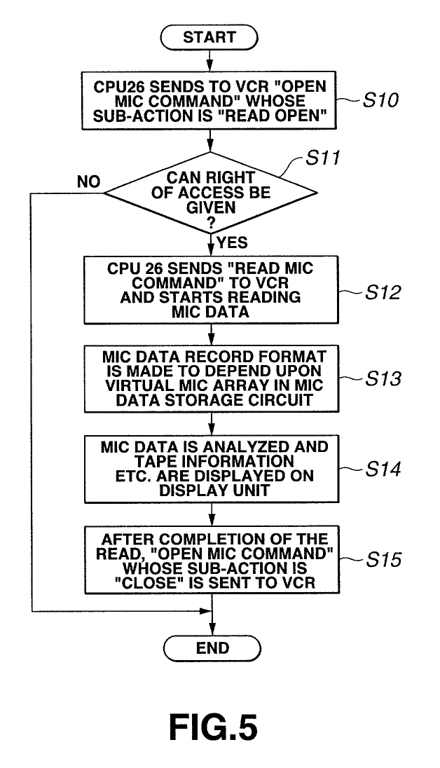

In the memory-in recording medium controlling system 1, the controller 20 connected via the transmission line 30 reads data from the MIC 15 of the DV tape 11 as will be described below with reference to FIG. 5:

When an application for edition of the data in the MIC 15 is started, the CPU 26 in the controller 20 transmits, at step S10, “OPEN MIC command” whose sub-function is “READ OPEN” to the VCR 10 in order to acquire the right of access to the MCI 15.

The VCR 10 will judge at step S11 whether the right of access to the MIC 15 can be given to the controller 20.

When the controller 20 can acquire the right of access to the MIC 15, the CPU 26 of the controller 20 will transmit “READ MIC command” to the VCR 10 and start reading MIC data at step S12. When the controller 20 cannot acquire the right, the process will be ended.

At step S13, the CPU 26 will save the read record format of the MCI 15 into the virtual MIC array in the MIC data storage circuit 21.

At step S14, the CPU 26 will analyze the MIC data and display tape information etc. in the graphical user interface screen shown in FIG. 4.

When the read of the data format of the MIC 15 is complete at step S15, the CPU 26 will transmit “OPEN MIC command” whose sub-function is “CLOSE” to the VCR 10 to release the right of access to the MIC 15.

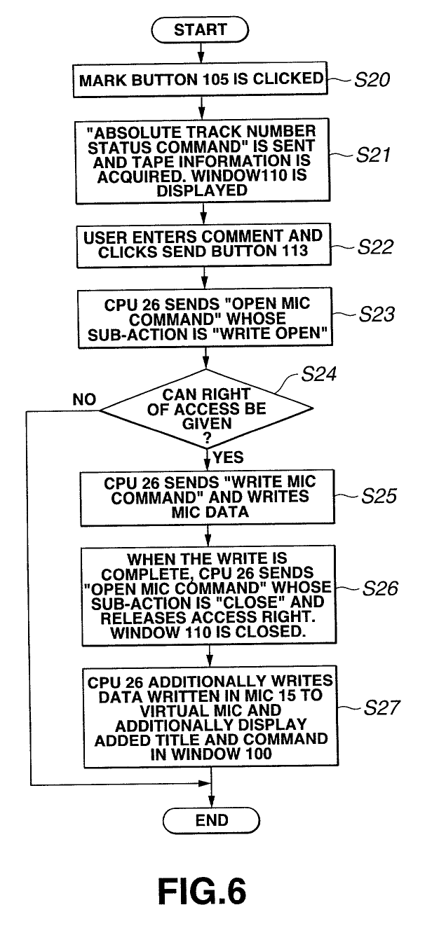

Therefore, the operations such as addition of a title, comment, etc. to a user-defined tape position will be made to the virtual MIC array of the MIC data storage circuit 21 as will be described below with reference to FIG. 6:

At step S20, the user clicks the MARK button 105 in the window 100 in FIG. 4 when a tape position where the user wants to add information is reached.

When the MARK button 105 is clicked, “ABSOLUTE TRACK NUMBER status command” is transmitted to the VCR 10 and tape position information on the tape position where the information is going to be added is acquired, at step S21. At the same time, the window 110 will be displayed.

At step S22, the user enters a title, comment, etc. from the input unit 21 of the controller 20 to the title input area 111 and comment input area 112, respectively, of the window 110, and clicks the SEND button 113 in the window 110.

When the SEND button 113 is clicked, the CPU 26 will transmit, at step S23, “OPEN MIC command” whose sub-function is “WRITE OPEN” to acquire the right of access to the MIC 15.

At step S24, the VCR 10 will judge whether the right of access can be given to the controller 20.

When the right of access can be acquired, the controller 20 will transmit, at step S25, “WRITE MIC command” for write of a comment, title and tape position information to the MIC 15, and register the information to the user-defined tape position. If the right of access cannot be acquired, the controller will end the process.

Upon completion of the write, the CPU 26 will to step S26, transmit “OPEN MIC command” whose sub-function is “CLOSE”, release the right of access to the MIC 15 and erase the window 110.

At step S27, the CPU 26 will add the data written in the MIC 15 to the virtual MIC array saved in the MIC data storage circuit 21, and additionally display the added title and command in the title area 101 and comment area 102, respectively, of the window 100.

When the user selects a title he wants to start playing back in the window 100 and clicks the SEARCH button 104 to select a tape position where a desired image is recorded from among pre-registered tape positions and to start playback of the image from the tape position, “ABSOLUTE TRACK NUMBER status command” is transmitted to the controller 20. At this time, the VCR 10 will skip the DV tape 11 to the tape position where the designated title is recorded and the user-defined image will be played back.

As having been described in the foregoing, the memory-in recording medium controlling system 1 adapted to control the memory of the recording medium can additionally write new appended information such as a title, comment, etc. to the data recorded in the MCI 15.

Also, the memory-in recording medium controlling system 1 can read appended information on the DV tape, stored in the MIC 15 built in the DV tape 11 by means of the controller 20 connected via the transmission line 30 and play back the information from the user-defined tape position.

What is claimed is:

1. A nonvolatile memory-in recording medium controlling system, comprising:
a recorder/player in which the recording medium is to be loaded, including:
means for writing and/or reading video and audio information to and/or from the memory-in recording medium; and
means for controlling data read and write from and to the nonvolatile memory; and
a controller connected to the recorded/player via a digital interface and including means for issuing a command for access to the nonvolatile memory via the digital interface and a command for data read from the nonvolatile memory and appending additional data to data thus read.

2. The controlling system as set forth in claim 1, wherein the controller has a storage means for storing data in the nonvolatile memory; and
the writing means writes data read from the nonvolatile memory to the storage means.

3. The controlling system as set forth in claim 1, wherein the digital interface is an IEEE 1394 serial bus conforming to IEEE Standard 1394-1995 “IEEE Standard for a High Performance Serial Bus”.

4. The controlling system as set forth in claim 1, wherein the controller includes:
an input means for making an input; and
a display means for displaying the contents of the input.

5. The controlling system as set forth in claim 1, wherein the commands are AV/C commands transmitted by the function control protocol.

6. The controlling system as set forth in claim 5, wherein the AV/C commands are transmitted and received by the asynchronous transfer.

7. A nonvolatile memory-in recording medium controller, comprising:
means for issuing a command for access to a nonvolatile memory of a nonvolatile memory-in recording medium via a digital interface and a command for data read from the nonvolatile memory and appending additional data to data thus read.

8. The controller as set forth in claim 7, wherein the controller has a storage means for storing data in the nonvolatile memory; and
the writing means writes data read from the nonvolatile memory to the storage means.

9. The controller as set forth in claim 7, wherein the digital interface is an IEEE 1394 serial bus conforming to IEEE Standard 1394-1995 “IEEE Standard for a High Performance Serial Bus”.

10. The controller as set forth in claim 7, wherein the controller includes an input means for making an input; and
a display means for displaying the contents of the input.

11. The controlling system as set forth in claim 7, wherein the commands are AV/C commands transmitted by the function control protocol.

12. The controlling system as set forth in claim 11, wherein the AV/C commands are transmitted and received by the asynchronous transfer.
